(19) United States
(12) Patent Application Publication
(10) Pub. No.: US 2023/0145098 A1
(43) Pub. Date: May 11, 2023

(54) Aerosol Generating Device with Battery Monitoring Arrangement

(71) Applicant: JT International SA, (US)

(72) Inventor: Mark Gill, London (GB)

(73) Assignees: JT International SA, Geneva (CH); JT International SA, Geneva (CH)

(21) Appl. No.: 17/767,600

(22) PCT Filed: Oct. 5, 2020
(86) PCT No.: PCT/EP2020/077892

§ 371 Date: Apr. 8, 2022

(30) Foreign Application Priority Data
Oct. 8, 2019 (EP) 19201971.9

(51) Int. Cl. A24F 40/53; G01B 7/16; G01R 31/54; A24F 40/20; A24F 40/40; A24F 40/57; H01M 10/42; H01M 10/48

(52) U.S. Cl. CPC A24F 40/53; G01B 7/18; G01R 31/54; A24F 40/20; A24F 40/40; A24F 40/57; H01M 10/425; H01M 10/48; H01M 2220/30; H01M 2200/00

(57) ABSTRACT

An aerosol generating device comprises a housing defining a cavity for receiving an aerosol generating substance, a controller and a rechargeable battery positioned in the housing (16). The controller is configured to detect expansion of the rechargeable battery in the housing.

### TECHNICAL FIELD

The present disclosure relates generally to an aerosol generating device, and more particularly to an aerosol generating device for heating an aerosol generating substance to generate an aerosol for inhalation by a user.

### TECHNICAL BACKGROUND

Devices which heat, rather than burn, an aerosol generating substance to produce an aerosol for inhalation have become popular with consumers in recent years. Such devices can use one of a number of different approaches to provide heat to the aerosol generating substance.

One approach is to provide an aerosol generating device which employs a resistive heating system. In such a device, a resistive heating element is provided to heat the aerosol generating substance and thereby generate a vapour which typically cools and condenses to form an aerosol for inhalation by a user of the device.

Another approach is to provide an aerosol generating device which employs an induction heating system. In such a device, an induction coil and a susceptor are provided. Electrical energy is supplied to the induction coil when a user activates the device which in turn generates an alternating electromagnetic field. The susceptor couples with the electromagnetic field and generates heat which is transferred, for example by conduction, to the aerosol generating substance thereby generating a vapour which typically cools and condenses to form an aerosol for inhalation by a user of the device.

Whichever approach is used to heat the aerosol generating substance, it may be preferable for the aerosol generating device to include a rechargeable battery to supply the required electrical power to the resistive heating element or the induction coil. The use of a rechargeable battery may, however, have certain drawbacks which the present disclosure seeks to mitigate.

### SUMMARY OF THE DISCLOSURE

According to a first aspect of the present disclosure, there is provided an aerosol generating device comprising:
a housing defining a cavity for receiving an aerosol generating substance;
a controller;
a rechargeable battery positioned in the housing;
wherein the controller is configured to detect expansion of the rechargeable battery in the housing.

The aerosol generating device is adapted to heat the aerosol generating substance, without burning the aerosol generating substance, to volatise at least one component of the aerosol generating substance and thereby generate a vapour which cools and condenses to form an aerosol for inhalation by a user of the aerosol generating device.

In general terms, a vapour is a substance in the gas phase at a temperature lower than its critical temperature, which means that the vapour can be condensed to a liquid by increasing its pressure without reducing the temperature, whereas an aerosol is a suspension of fine solid particles or liquid droplets, in air or another gas. It should, however, be noted that the terms ‘aerosol’ and ‘vapour’ may be used interchangeably in this specification, particularly with regard to the form of the inhalable medium that is generated for inhalation by a user.

Detection of physical expansion of the rechargeable battery is readily achieved by the controller, thereby avoiding potential damage to the aerosol generating device, for example by allowing use of the device to be discontinued and/or by enabling action to be taken to replace the rechargeable battery and/or by enabling the controller to modify how the rechargeable battery is charged and/or discharged.

The aerosol generating device may include an electrically conductive component having an electrical characteristic which varies in response to expansion of the rechargeable battery in the housing. The electrically conductive component may be positioned in the housing such that the electrically conductive component is deformed by expansion of the rechargeable battery in the housing. The variation of the electrical characteristic of the electrically conductive component provides a reliable indication that there is physical expansion of the rechargeable battery.

The electrical characteristic of the electrically conductive component may vary based on the deformation of the electrically conductive component. The extent of the physical expansion of the rechargeable battery can, thus, be determined based on the variation of the electrical characteristic. For example, a small variation in the electrical characteristic may indicate that there is a small amount of physical expansion of the rechargeable battery which may not warrant intervention or replacement, whereas a large variation in the electrical characteristic may indicate that there is a large amount of physical expansion of the rechargeable battery which may warrant intervention or replacement.

The controller may be configured to detect expansion of the rechargeable battery based on a detected variation of the electrical characteristic of the electrically conductive component. The controller can thus reliably detect any physical expansion of the rechargeable battery based on the variation of the electrical characteristic of the electrically conductive component.

The rechargeable battery may comprise one or more rechargeable cells contained within a battery housing. The battery housing may have any suitable geometry, and may for example be substantially cylindrical, substantially button-shaped or coin-shaped, or substantially rectangular. These housing geometries are given purely by way of example, and it will be apparent to one of ordinary skill in the art that other housing geometries could be employed and are entirely within the scope of the present disclosure.

The electrical characteristic may include an electrical resistance of the electrically conductive component and the controller may be configured to monitor the electrical resistance of the electrically conductive component. With this arrangement, the controller may be configured to detect physical expansion of the rechargeable battery based on a detected change in the electrical resistance of the electrically conductive component.

The electrical characteristic may include an electrical conductivity of the electrically conductive component and the controller may be configured to detect a break in the electrical conductivity. For example, the electrically conductive component may be configured to be pulled apart and to mechanically fail under tension in the event that the rechargeable battery expands. With this arrangement, the controller may be configured to detect physical expansion of the battery based on a detected break in the electrical conductivity of the electrically conductive component.

The electrically conductive component may extend around at least part of an outer surface of the rechargeable battery. The structure of the aerosol generating device may be simplified.

The electrically conductive component may extend substantially along the whole perimeter (e.g. circumference) of the rechargeable battery. This may allow any expansion of the rechargeable battery to be reliably detected.

The electrically conductive component may extend around an outer surface of the rechargeable battery over a distance which is greater than a perimeter (e.g. circumference) of the rechargeable battery. Opposite ends of the electrically conductive component may be displaced relative to each other in an axial direction of the rechargeable battery. In one example, the electrically conductive component may be wound diagonally or helically around the rechargeable battery. In another example, one or more portions of the electrically conductive component may extend substantially in an axial direction of the rechargeable battery. With these arrangements, the electrically conductive component may cover a larger surface area of the rechargeable battery, thereby enabling expansion of the rechargeable battery to be more reliably detected.

The electrically conductive component may be disposed on an outer surface of the rechargeable battery. For example, the electrically conductive component could be coated, adhered, printed, deposited or otherwise manufactured onto the outer surface of the rechargeable battery. The direct and intimate contact between the electrically conductive component and the outer surface of the rechargeable battery may facilitate the detection of expansion of the rechargeable battery and may allow the structure of the aerosol generating device to be simplified.

The electrically conductive component may be positioned adjacent to an outer surface of the rechargeable battery. In this example, the electrically conductive component may be an integral component part of the aerosol generating device. For example, the electrically conductive component may be disposed on the housing of the aerosol generating device.

The electrically conductive component may comprise an electrically conductive track or an electrically conductive strip.

The controller may be configured to generate an alert upon detecting expansion of the rechargeable battery. This may allow a user of the aerosol generating device to take appropriate action, for example by ceasing use of the device and possibly removing and replacing the rechargeable battery.

The aerosol generating device may include a heater electrically connected to the rechargeable battery and arranged to heat an aerosol generating substance positioned in the cavity and the controller may be configured to electrically disconnect the heater from the rechargeable battery upon detecting expansion of the rechargeable battery. Further use of the device, and potential further physical expansion of the rechargeable battery, may be prevented. This may minimise the risk of the aerosol generating device being physically damaged by preventing continued use.

The heater may comprise a resistive heater. The resistive heater may comprise a resistive heating element. The resistive heating element may comprise an electrically resistive material. Examples of suitable electrically resistive materials include, but are not limited to, metals, metal alloys, electrically conductive ceramics, for example tungsten and alloys thereof, and composite materials comprising a metallic material and a ceramic material.

The heater may comprise an induction coil arranged to generate an alternating electromagnetic field for inductively heating an induction heatable susceptor. The induction coil may comprise a Litz wire or a Litz cable. It will, however, be understood that other materials could be used. The induction coil may extend around the cavity.

The induction coil could be substantially helical in shape. The circular cross-section of a helical induction coil may facilitate the insertion of an aerosol generating substance, or for example an aerosol generating article containing the aerosol generating substance and optionally one or more induction heatable susceptors, into the cavity and ensure uniform heating of the aerosol generating substance.

The induction heatable susceptor(s) may comprise one or more, but not limited, of aluminium, iron, nickel, stainless steel and alloys thereof, e.g. Nickel Chromium or Nickel Copper. With the application of an electromagnetic field in its vicinity, the susceptor(s) may generate heat due to eddy currents and magnetic hysteresis losses resulting in a conversion of energy from electromagnetic to heat.

The induction coil may be arranged to operate in use with a fluctuating electromagnetic field having a magnetic flux density of between approximately 20 mT and approximately 2.0 T at the point of highest concentration.

The controller may include electronic circuitry. The rechargeable battery and the electronic circuitry may be configured to operate at a high frequency. The rechargeable battery and the electronic circuitry may be configured to operate at a frequency of between approximately 80 kHz and 500 kHz, possibly between approximately 150 kHz and 250 kHz, and possibly at approximately 200 kHz. The rechargeable battery and the electronic circuitry could be configured to operate at a higher frequency, for example in the MHz range, depending on the type of inductively heatable susceptor that is used.

The aerosol generating substance may be any type of solid or semi-solid material. Example types of aerosol generating solids include powder, granules, pellets, shreds, strands, particles, gel, strips, loose leaves, cut leaves, cut filler, porous material, foam material or sheets. The aerosol generating substance may comprise plant derived material and in particular, may comprise tobacco. It may advantageously comprise reconstituted tobacco.

The aerosol generating substance may be circumscribed by a paper wrapper and may, thus, be embodied as an aerosol generating article. The aerosol generating article may be formed substantially in the shape of a stick. The aerosol generating article may include a filter, for example comprising cellulose acetate fibres. The filter may be in abutting coaxial alignment with the aerosol generating substance.

The aerosol generating substance may be arranged inside a shell and may, thus, be embodied as an aerosol generating article. The shell may be an air-permeable shell and may comprise a material which is electrically insulating and non-magnetic. The shell may comprise an air-permeable material, for example a porous material. The material may have a high air permeability to allow air to flow through the material with a resistance to high temperatures. Examples of suitable air-permeable materials include cellulose fibres, paper, cotton and silk. The air-permeable material may also act as a filter. Alternatively, the shell may comprise a material that is not air permeable, e.g., a non-porous material, but which includes perforations or openings to allow air to flow through the shell.

The aerosol generating substance may comprise an aerosol-former. Examples of aerosol-formers include polyhydric alcohols and mixtures thereof such as glycerine or propylene glycol. Typically, the aerosol generating substance may comprise an aerosol-former content of between approximately 5% and approximately 50% on a dry weight basis. In some embodiments, the aerosol generating substance may comprise an aerosol-former content of between approximately 10% and approximately 20% on a dry weight basis, and possibly approximately 15% on a dry weight basis.

In another example, the aerosol generating substance may be the aerosol-former itself. The aerosol generating substance may, therefore, be a liquid. In this case, the aerosol generating device may include a liquid transfer element (e.g. a wick) associated with the heater which allows the liquid to be vaporized by the heater and allows a vapour to be formed and released/emitted from the liquid transfer element, the vapour subsequently cooling and condensing to form an aerosol suitable for inhalation by a user of the aerosol generating device.

Upon heating, the aerosol generating substance may release volatile compounds. The volatile compounds may include nicotine or flavour compounds such as tobacco flavouring.

### BRIEF DESCRIPTION OF THE DRAWINGS

FIG. 1 is a diagrammatic cross-sectional view of an example of an aerosol generating device including a rechargeable battery and an electrically conductive component which extends around the outer surface of the battery;

FIGS. 2 and 3 are diagrammatic cross-sectional views along the line A-A in FIG. 1, showing the rechargeable battery respectively in an unexpanded state and an expanded state;

FIGS. 4 and 5 are diagrammatic views similar to FIGS. 2 and 3 of an alternative example in which an electrically conductive component extends around part of the outer surface of the rechargeable battery; and

FIG. 6 is a diagrammatic cross-sectional view similar to FIG. 1 showing only the rechargeable battery and an electrically conductive component which extends helically around an outer surface of the rechargeable battery.

### DETAILED DESCRIPTION OF EMBODIMENTS

Embodiments of the present disclosure will now be described by way of example only and with reference to the accompanying drawings.

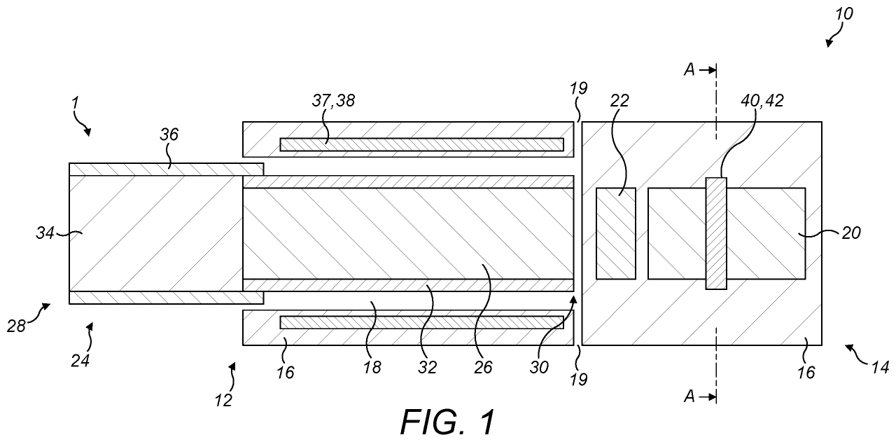

Referring initially to FIGS. 1 to 3, there is shown diagrammatically an example of an aerosol generating system 1. The aerosol generating system 1 comprises an aerosol generating device 10 and an example of an aerosol generating article 24. The aerosol generating device 10 has a proximal end 12 and a distal end 14 and comprises a housing 16 which defines a cavity 18. The housing 16 includes one or more air inlets 19 for supplying air to the cavity 18. The aerosol generating device 10 further includes a power source in the form of a rechargeable battery 20, and a controller 22. Although only one rechargeable battery 20 is illustrated in FIG. 1, it will be understood that the power source could comprise a plurality of rechargeable batteries 20 and that the or each rechargeable battery 20 may, for example, be inductively rechargeable.

The aerosol generating device 10 is generally cylindrical and the cavity 18 defined by the housing 16 is also cylindrical and takes the form of a cylindrical heating compartment. The cavity 18 is arranged to receive a correspondingly shaped generally cylindrical or rod-shaped aerosol generating article 24 comprising an aerosol generating substance 26. The aerosol generating article 24 is a disposable article which may, for example, contain tobacco as the aerosol generating substance 26. The aerosol generating article 24 has first and second ends 28, 30 and comprises a paper wrapper 32 surrounding the aerosol generating substance 26. The aerosol generating article 24 also comprises a filter 34 at the first end 28 which is in abutting coaxial alignment with the aerosol generating substance 26 and the paper wrapper 32. The filter 34 acts as a mouthpiece and comprises an air-permeable plug, for example comprising cellulose acetate fibres. Both the paper wrapper 32 and the filter 34 are overwrapped by an outer wrapper 36 typically comprising tipping paper. In an alternative example not illustrated in the drawings, the filter 34 could be omitted and instead the aerosol generating device 10 could include an integrated mouthpiece.

The aerosol generating device 10 includes a heater 37 for heating the aerosol generating substance 26 without burning the aerosol generating substance 26. In the illustrated embodiment, the heater 37 comprises a resistive heating element 38 which is positioned radially outwardly of the cavity 18 and which extends around the cavity 18.

During operation of the aerosol generating system 1, an electric current is supplied to the resistive heating element 38 causing it to heat up. The heat from the resistive heating element 38 is transferred to the aerosol generating substance 26 positioned in the cavity 18, for example by conduction, radiation and convection, to heat the aerosol generating substance 26 and thereby generate a vapour which cools and condenses to form an aerosol for inhalation by a user of the aerosol generating system 1. The vaporisation of the aerosol generating substance 26 is facilitated by the addition of air from the surrounding environment through the air inlets 19.

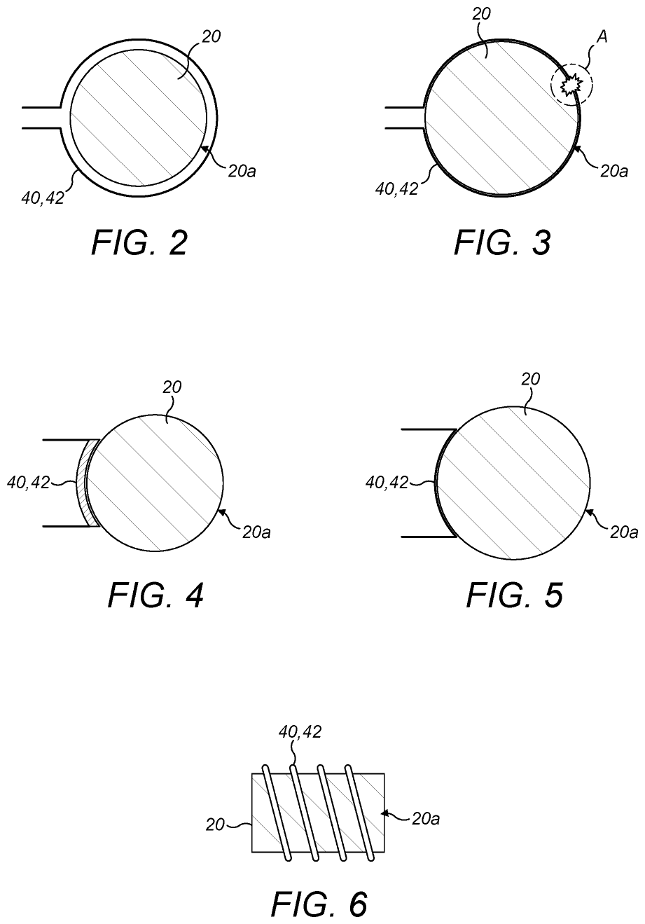

The aerosol generating device 10 includes an electrically conductive component 40 in the form of an electrically conductive track 42. In the example illustrated in FIGS. 1 to 3, the rechargeable battery 20 is substantially circular in cross-section and the electrically conductive track 42 extends circumferentially around an outer surface 20a of the rechargeable battery 20, substantially around the whole circumference. As will be apparent from the cross-sectional view of FIG. 2 which shows the rechargeable battery 20 in an unexpanded state, the electrically conductive track 42 is positioned adjacent to the outer surface 20a of the rechargeable battery 20. More particularly, the electrically conductive track 42 is disposed on the housing 16 inside a battery compartment in which the rechargeable battery 20 is positioned. In another example (not illustrated), the electrically conductive track 42 may be disposed on the outer surface 20a of the rechargeable battery 20, for example by being coated, adhered, printed, deposited or otherwise manufactured onto the outer surface 20a of the rechargeable battery 20. In both cases, the electrically conductive track 42 is arranged so that when the rechargeable battery 20 is in an unexpanded state as shown in FIG. 2, the electrically conductive track 42 remains intact and electrically conductive.

In the example illustrated in FIGS. 1 to 3, the electrically conductive track 42 is formed of a material which is substantially inextensible. Thus, if the rechargeable battery 20 expands by a predetermined amount or beyond a predetermined threshold, the electrically conductive track 42 is pulled apart and breaks under tension, for example at the point designated A in FIG. 3, resulting in a break in the electrical conductivity of the electrically conductive track 42. The controller 22 can be configured to detect the break in the electrical conductivity of the electrically conductive track 42 and to thereby detect expansion of the rechargeable battery 20 in the housing 16.

In another example illustrated in FIGS. 4 and 5, the electrically conductive track 42 extends around only part of the outer surface 20a of the rechargeable battery 20. The electrically conductive track 42 comprises an extensible material which is caused to mechanically extend under tension when the rechargeable battery 20 expands in the housing 16. The extension of the electrically conductive track 42 due to expansion of the rechargeable battery 20 is apparent from a comparison of FIGS. 4 and 5. The electrically conductive track 42 has a resistance which changes (e.g. increases or decreases) as it is deformed, and in particular as it is extended. The controller 22 can be configured to detect the change in the resistance of the electrically conductive track 42 and to thereby detect expansion of the rechargeable battery 20 in the housing 16.

In some embodiments, the controller 22 may be configured to generate an alert upon detecting expansion of the rechargeable battery 20, for example based on a detected break in the electrical conductivity of the electrically conductive track 42 (FIGS. 2 and 3) or based on a detected change in the resistance of the electrically conductive track 42 (FIGS. 4 and 5). The alert may notify a user of the aerosol generating device 10 that expansion of the battery 20 has been detected, for example enabling the user to cease use of the device 10 and/or to replace the rechargeable battery 20. Alternatively or in addition, the controller 20 may be configured to electrically disconnect the resistive heating element 38 from the rechargeable battery 20 upon detecting physical expansion of the rechargeable battery 20 and/or to modify the charge and/or discharge characteristics of the rechargeable battery 20, for example to minimise the rate of further expansion and to prolong the useful life of the rechargeable battery 20.

Referring now to FIG. 6, there is shown an alternative example of an electrically conductive track 42 which extends helically around the outer surface 20a of the rechargeable battery 20. In this alternative example, the electrically conductive track 42 extends around the outer surface 20a by a total distance which is greater than the circumference of the rechargeable battery 20. As noted above, arrangements in which the electrically conductive track 42 extends around the outer surface 20a of the rechargeable battery 20 by a distance which is greater than its circumference may allow expansion of the rechargeable battery 20 to be more reliably detected because the electrically conductive track 42 covers a larger surface area of the rechargeable battery 20.

Although exemplary embodiments have been described in the preceding paragraphs, it should be understood that various modifications may be made to those embodiments without departing from the scope of the appended claim. Thus, the breadth and scope of the claim should not be limited to the above-described exemplary embodiments.

Any combination of the above-described features in all possible variations thereof is encompassed by the present disclosure unless otherwise indicated herein or otherwise clearly contradicted by context.

Unless the context clearly requires otherwise, throughout the description and the claim, the words “comprise”, “comprising”, and the like, are to be construed in an inclusive as opposed to an exclusive or exhaustive sense; that is to say, in the sense of “including, but not limited to”.

1. An aerosol generating device comprising:
a housing defining a cavity for receiving an aerosol generating substance;
a controller;
a rechargeable battery positioned in the housing;
wherein the controller is configured to detect expansion of the rechargeable battery in the housing.

2. An aerosol generating device according to claim 1, wherein the aerosol generating device includes an electrically conductive component having an electrical characteristic which varies in response to expansion of the rechargeable battery in the housing.

3. An aerosol generating device according to claim 2, wherein the electrically conductive component is positioned in the housing such that the electrically conductive component is deformed by expansion of the rechargeable battery in the housing.

4. An aerosol generating device according to claim 3, wherein the electrical characteristic of the electrically conductive component varies based on the deformation of the electrically conductive component.

5. An aerosol generating device according to claim 2, wherein the controller is configured to detect expansion of the rechargeable battery based on a detected variation of the electrical characteristic of the electrically conductive component.

6. An aerosol generating device according to claim 2, wherein the electrical characteristic includes an electrical resistance of the electrically conductive component, and wherein the controller is configured to monitor the electrical resistance of the electrically conductive component.

7. An aerosol generating device according to claim 2, wherein the electrical characteristic includes an electrical conductivity of the electrically conductive component, and wherein the controller is configured to detect a break in the electrical conductivity.

8. An aerosol generating device according to claim 2, wherein the electrically conductive component extends around at least part of an outer surface of the rechargeable battery.

9. An aerosol generating device according to claim 2, wherein the electrically conductive component extends substantially along the whole perimeter of the rechargeable battery.

10. An aerosol generating device according to claim 2, wherein the electrically conductive component extends around an outer surface of the rechargeable battery over a distance which is greater than a perimeter of the rechargeable battery.

11. An aerosol generating device according to claim 10, wherein opposite ends of the electrically conductive component are arranged so as to be displaced relative to each other in an axial direction of the rechargeable battery due to expansion of the rechargeable battery.

12. An aerosol generating device according to claim 2, wherein the electrically conductive component is disposed on an outer surface of the rechargeable battery.

13. An aerosol generating device according to claim 2, wherein the electrically conductive component is positioned adjacent to an outer surface of the rechargeable battery.

14. An aerosol generating device according to claim 1, wherein the controller is configured to generate an alert upon detecting expansion of the rechargeable battery.

15. An aerosol generating device according to claim 1, wherein the aerosol generating device includes a heater electrically connected to the rechargeable battery and arranged to heat an aerosol generating substance positioned in the cavity, and wherein the controller is configured to electrically disconnect the heater from the rechargeable battery upon detecting expansion of the rechargeable battery.
